(19) United States
(12) Patent Application Publication
(10) Pub. No.: US 2012/0199072 A1
(43) Pub. Date: Aug. 9, 2012

(54) METHOD AND APPARATUS FOR MANUFACTURING SILICON THIN FILM LAYER AND MANUFACTURING APPARATUS OF SOLAR CELL

(76) Inventors: Dongjoo You, Seoul (KR); Sehwon Ahn, Seoul (KR); Heonmin Lee, Seoul (KR); Sunho Kim, Seoul (KR); Jeonghun Son, Seoul (KR)

(21) Appl. No.: 13/449,054

(22) Filed: Apr. 17, 2012

Related U.S. Application Data
(62) Division of application No. 12/708,343, filed on Feb. 18, 2010.

(30) Foreign Application Priority Data
Feb. 19, 2009 (KR) 10-2009-0013857

(51) Int. Cl. C23C 16/24; C23C 16/455

(52) U.S. Cl. 118/724

(57) ABSTRACT

A method and apparatus for manufacturing a silicon thin film layer and a manufacturing apparatus of a solar cell are disclosed. The manufacturing apparatus of solar cell comprises an outer chamber; an inner chamber disposed within the outer chamber; a container disposed at the inner chamber and which receives a fluid; and a heat exchanger disposed at the outside of the outer chamber and which exchanges heat of the fluid.

This application is a Divisional of co-pending U.S. application Ser. No. 12/708,343, filed on Feb. 18, 2010, which claims the priority and the benefit of Korean Patent Application No. 10-2009-0013857 filed on Feb. 19, 2009, the entire contents of both of which are incorporated herein by reference for all purposes as if fully set forth herein.

### BACKGROUND OF THE INVENTION

1. Field of the Invention

Embodiments of the invention relate to a method and apparatus for manufacturing a silicon thin film layer and a manufacturing apparatus of a solar cell.

2. Discussion of the Related Art

A silicon thin film layer is widely used in various semiconductor elements. Such a silicon thin film layer can be manufactured using a plasma deposition method.

As an example of an element comprising the silicon thin film layer, a solar cell is exemplified.

The solar cell is an element for converting light to electricity and comprises a p-type semiconductor and an n-type semiconductor.

In general, when light is applied from the outside, pairs of electrons and holes are formed within a semiconductor of the solar cell by the applied light, and electrons move to an n-type semiconductor and holes move to a p-type semiconductor by an electric field generated within the semiconductor, thereby generating electric power.

### SUMMARY OF THE INVENTION

In one aspect, there is a silicon thin film layer manufacturing apparatus including an outer chamber, an inner chamber disposed within the outer chamber, a container disposed at the inner chamber and which receives a fluid, and a heat exchanger disposed at the outside of the outer chamber and which exchanges heat of the fluid.

The fluid is water or a GALDEN solution.

A supporting member in which a substrate having a deposited silicon thin film layer is disposed is provided in the inner chamber.

At least one distribution plate is separated from the supporting member and is in which a plurality of orifices are formed.

The at least one distribution plate includes a first distribution plate and a second distribution plate, the second distribution plate is disposed between a discharge port of a gas supply pipe and the supporting member, the gas supply pipe supplying gas into the inner chamber, and the first distribution plate is disposed between the second distribution plate and the supporting member.

A dispersion portion is disposed between the second distribution plate and the discharge port of the gas supply pipe.

The dispersion portion has a plate shape.

The number of plurality of orifices of the first distribution plate is larger than the number of plurality of orifices of the second distribution plate.

A gap of plurality of orifices of the first distribution plate is smaller than a gap of plurality of orifices of the second distribution plate.

A width of plurality of orifices of the first distribution plate is smaller than a width of plurality of orifices of the second distribution plate.

At least one of the first distribution plate and the second distribution plate includes an aluminum material (Al).

The silicon thin film layer manufacturing apparatus further including a supply pipe which supplies the fluid from the heat exchanger to the container and a recovery pipe which recovers the fluid from the container to the heat exchanger.

The supply pipe and the recovery pipe are disposed around a gas supply pipe which supplies gas into the inner chamber.

In another aspect, there is a method of manufacturing a silicon thin film layer using a silicon thin film layer manufacturing apparatus having an outer chamber, an inner chamber disposed within the outer chamber, a container disposed at the inner chamber and which receives a fluid, and a heat exchanger disposed at the outside of the outer chamber and which exchanges heat of the fluid, the method including adjusting a temperature of process gas injected into the inner chamber and dispersing the process gas having the adjusted temperature within the inner chamber.

In another aspect, there is a solar cell manufacturing apparatus including an outer chamber, an inner chamber disposed within the outer chamber, a container disposed at the inner chamber and which receives a fluid, and a heat exchanger disposed at the outside of the outer chamber and which exchanges heat of the fluid.

The fluid is water or a GALDEN solution.

A supporting member in which a substrate having a deposited silicon thin film layer is disposed is provided in the inner chamber.

The solar cell manufacturing apparatus further including at least one distribution plate separated from the supporting member and in which a plurality of orifices are formed.

The at least one distribution plate includes a first distribution plate and a second distribution plate, the second distribution plate is disposed between a discharge port of a gas supply pipe and the supporting member, the gas supply pipe supplying gas into the inner chamber, and the first distribution plate is disposed between the second distribution plate and the supporting member.

A dispersion portion is disposed between the second distribution plate and the discharge port of the gas supply pipe.

### BRIEF DESCRIPTION OF THE DRAWINGS

FIG. 1 is a view illustrating an example of a solar cell;

FIGS. 2 to 4 are views illustrating an apparatus and method for manufacturing a silicon thin film layer according to an embodiment of the invention;

FIGS. 5 to 10 are views related to comparing a manufacturing apparatus according an embodiment of the invention and a manufacturing apparatus according to a Comparative Example; and

FIG. 11 is a view illustrating an example of another configuration of a silicon thin film layer manufacturing apparatus according to an embodiment of the invention.

### DETAILED DESCRIPTION OF THE EMBODIMENTS

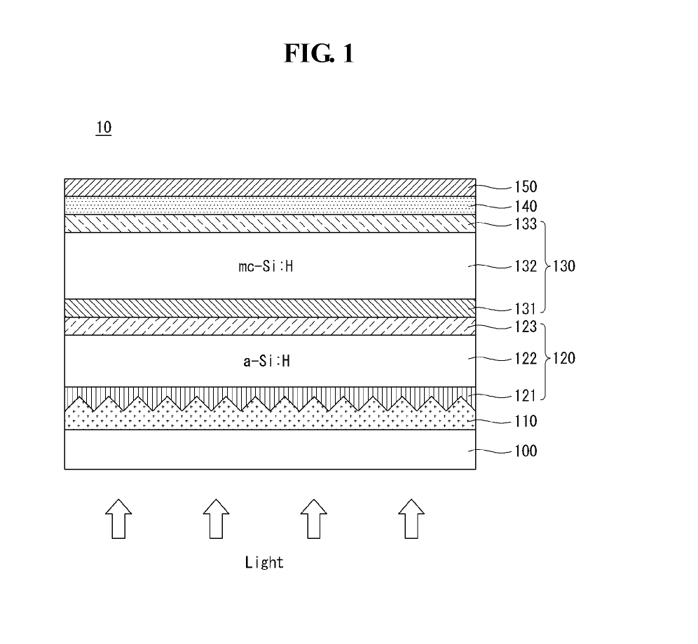

FIG. 1 is a view illustrating an example of a solar cell.

For example, as shown in FIG. 1, a solar cell 10 comprises a substrate 100, a first electrode 110 formed on the substrate 100, a first photoelectric conversion layer 120 and a second photoelectric conversion layer 130 formed on the first electrode 110, a reflective layer 140 formed on the second photoelectric conversion 130, and a second electrode 150.

At least one of the first photoelectric conversion layer 120 and the second photoelectric conversion layer 130 comprises a micro-crystalline silicon layer. Preferably, though not required, the first photoelectric conversion layer 120 and the second photoelectric conversion layer 130 are sequentially disposed from a light incidence plane of the solar cell, and the second photoelectric conversion layer 130 comprises a micro-crystalline silicon layer.

Hereinafter, it is assumed that the first photoelectric conversion layer 120 is made of an amorphous silicon (a-Si) material and the second photoelectric conversion layer 130 is made of a micro-crystalline silicon (mc-Si) material.

The solar cell 10 according to an embodiment of the invention is not limited to a structure of FIG. 1 and may have any structure comprising a micro-crystalline silicon layer. For example, the solar cell 10 may be formed in a double junction structure (pin-pin structure) of FIG. 1, a single junction structure (pin structure) made of a micro-crystalline silicon material, and a triple junction structure (pin-pin-pin structure).

Here, the first electrode 110 is a front electrode and the second electrode 150 is a rear electrode.

The substrate 100 provides space in which other functional layers may be disposed. Further, the substrate 100 may be made of a substantially transparent material, for example a glass or plastic material so that applied light more effectively arrive in the first and second photoelectric conversion layers 120 and 130.

In order to enhance a transmittance of applied light, the first electrode 110 comprises a material having electrical conductivity while having substantial transparency. For example, the front electrode 110 may be made of a material selected from a group consisting of indium tin oxide (ITO), tin-based oxide (SnO₂), AgO, ZnO—(Ga₂O₃ or Al₂O₃), fluorine tin oxide (FTO), and mixtures thereof having a high light transmittance and high electrical conductivity in order to pass through most light and to allow electricity to flow well.

The first electrode 110 is formed on a substantially entire surface of the substrate 100 and is electrically connected to the first photoelectric conversion layer 120. Accordingly, the first electrode 110 may collect the holes as a carrier generated by applied light and output the holes.

Further, a plurality of unevenness having a random pyramid structure may be formed on an upper surface of the first electrode 110. That is, the first electrode 110 has a texturing surface. In this way, by texturing a surface of the first electrode 110, reflection of applied light may be reduced and an absorption rate of light may be enhanced and thus efficiency of the solar cell 10 may be improved.

FIG. 1 illustrates a case where unevenness is formed only on the first electrode 110, but unevenness may be formed on the first and second photoelectric conversion layers 120 and 130. Hereinafter, for convenience of description, a case where unevenness is formed only on the first electrode 110 is exemplified.

The second electrode 150 comprises a metal material having excellent electrical conductivity in order to enhance recovery efficiency of electric power generated by the first and second photoelectric conversion layers 120 and 130. Further, the second electrode 150 collects the electrons as a carrier generated by applied light as electrically connected to the second photoelectric conversion layer 130 and outputs the electrons.

The reflective layer 140 again reflects light transmitted through the first and second photoelectric conversion layers 120 and 130 toward the first and second photoelectric conversion layers 120 and 130. Accordingly, the first and second photoelectric conversion layers 120 and 130 may increase generation of electric power using light reflected by the reflective layer 140. Accordingly, efficiency of the solar cell 10 may be improved.

The first and second photoelectric conversion layers 120 and 130 may convert light applied from the outside to electricity.

The first photoelectric conversion layer 120 comprises a first p-type semiconductor layer 121, a first i-type semiconductor layer 122, and a first n-type semiconductor layer 123. All of the first p-type semiconductor layer 121, the first i-type semiconductor layer 122, and the first n-type semiconductor layer 123 may be made of an amorphous silicon material.

The first p-type semiconductor layer 121 may be formed by using a gas comprising impurities of a trivalent element such as boron, gallium, and indium in a raw material gas comprising silicon (Si).

The first i-type semiconductor layer 122 may reduce a recombination rate of a carrier and absorb light. The first i-type semiconductor layer 122 may generate a carrier such as an electron and a hole by absorbing applied light.

The first n-type semiconductor layer 123 may be formed by using a gas comprising impurities of a pentavalent element such as phosphorus (P), arsenic (As), and antimony (Sb) in a raw material gas comprising silicon.

The second photoelectric conversion layer 130 may be a silicon cell using a micro-crystalline silicon material, for example hydrogenated micro-crystalline silicon (mc-Si:H).

The second photoelectric conversion layer 130 comprises a second p-type semiconductor layer 131, a second i-type semiconductor layer 132, and a second n-type semiconductor layer 133 sequentially formed.

It is preferable that the second i-type semiconductor layer 132 of the second photoelectric conversion layer 130 is a micro-crystalline silicon layer comprising a micro-crystalline silicon material. Alternatively, all of the second p-type semiconductor layer 131, the second i-type semiconductor layer 132, and the second n-type semiconductor layer 133 of the second photoelectric conversion layer 130 may comprise a micro-crystalline silicon material.

In such a structure, when light is applied toward the first electrode 110, depletion is formed by the p-type semiconductor layers 121 and 131 and the n-type semiconductor layers 123 and 133 having a relatively high doping density within the i-type semiconductor layers 122 and 132, thereby forming an electric field. Electrons and holes generated in the i-type semiconductor layers 122 and 132, which are a light absorption layer by the photovoltaic effect are separated by a contact potential difference and move in different directions. For example, holes move toward the first electrode 110, and electrons move toward the second electrode 150. Electric power may be generated in this way.

The first i-type semiconductor layer 122 may generate electrons and holes by mainly absorbing light of a short wavelength band. Further, the second i-type semiconductor layer 132 may generate electrons and holes by mainly absorbing light of a long wavelength band.

In this way, the solar cell 10 having a double junction structure of FIG. 1 generates carriers by absorbing light of a short wavelength band and a long wavelength band, thereby having high efficiency.

A manufacturing process of the solar cell 10 comprises a plasma deposition process. In the plasma deposition process, a characteristic of a deposited silicon thin film layer according to a process temperature changes. For example, when manufacturing the second photoelectric conversion layer 130 with a plasma deposition process, if a process temperature is excessively high, a property of the second photoelectric conversion layer 130 approaches an amorphous silicon material, and if a process temperature is excessively low, a property of the second photoelectric conversion layer 130 approaches a crystalline structure silicon material.

Therefore, in order to manufacture the second photoelectric conversion layer 130 comprising a micro-crystalline silicon material having an intermediate property of amorphous silicon and crystalline silicon using a plasma deposition process, it is preferable to uniformly adjust a process temperature.

Further, due to a property of a thin film layer of the second photoelectric conversion layer 130, the second photoelectric conversion layer 130 has an optical absorption property relatively lower than that of the first photoelectric conversion layer 120, and thus the first photoelectric conversion layer 120 made of an amorphous silicon material should have a thick thickness.

Now Therefore, it is necessary to more minutely control a process temperature of the second photoelectric conversion layer 130 in a plasma deposition process than the first photoelectric conversion layer 120.

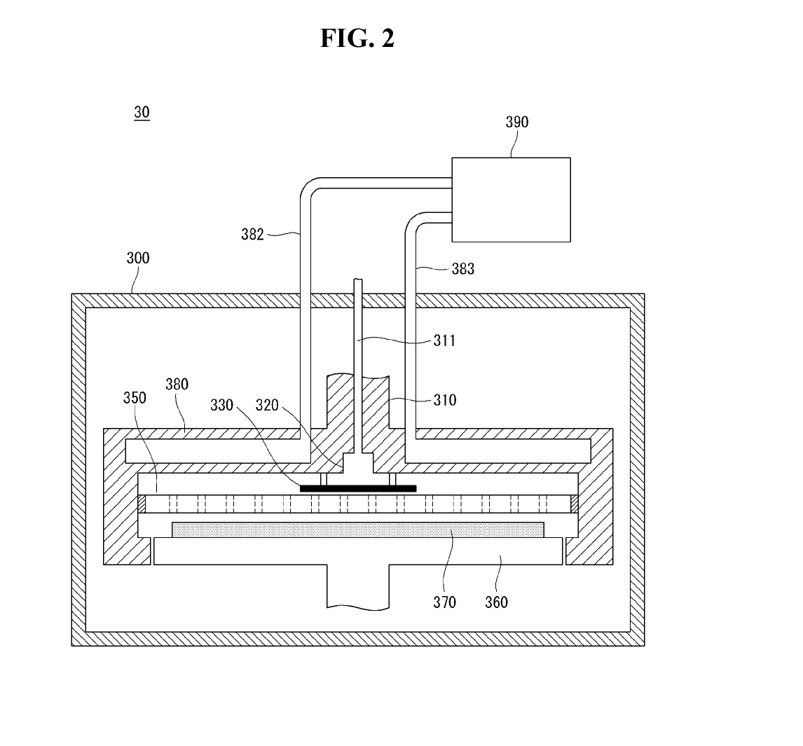

FIGS. 2 to 4 are views illustrating an apparatus and method for manufacturing a silicon thin film layer according to an embodiment of the invention. Hereinafter, the apparatus and method for manufacturing a silicon thin film layer according to an embodiment of the invention are focused to a case of manufacturing a micro-crystalline silicon thin film layer of a solar cell, but can also be applied to any case of generally forming a silicon thin film layer, for example, a case of manufacturing a silicon thin film layer of a liquid crystal display (LCD) or an amorphous silicon thin film layer.

Referring to FIG. 2, a manufacture apparatus 30 of a silicon thin film layer according to an embodiment of the invention comprises an outer chamber 300, an inner chamber 310 disposed within the outer chamber 300 and at which the substrate 370 is disposed, a container 380 disposed at the inner chamber 310 and for injecting fluid, and a heat exchanger 390 disposed at the outside of the outer chamber 300 and for exchanging heat of fluid injected to the container 380.

Specifically, a supporting member 360 is disposed at the inner chamber 310, and the substrate 370 having a deposited silicon thin film layer is disposed at the supporting member 360. Here, the supporting member 360 supports the substrate 370 and applies heat to the substrate 370. Further, the supporting member 360 is used as a positive electrode. Further, the supporting member 360 uniformly applies heat regardless of a position of the substrate 370.

The outer chamber 300 increases a vacuum degree within the outer chamber 300.

Further, the manufacture apparatus 30 of a solar cell comprises a dispersion portion 330 and a distribution plate 350.

The distribution plate 350 is separated by a predetermined distance from the supporting member 360 within the inner chamber 310. Further, even if the substrate 370 is disposed at the supporting member 360, the distribution plate 350 is separated from the substrate 370.

The manufacturing apparatus according to an embodiment of the invention comprises at least one distribution plate 350.

Further, the distribution plate 350 is used as a negative electrode.

Further, the distribution plate 350 comprises a plurality of orifices. Here, each orifice is a predetermined penetration hole through which reaction gas can pass.

The dispersion portion 330 is disposed between the distribution plate 350 and the gas discharge port 320 of a gas supply pipe 311 for supplying gas to the inner chamber 310.

The dispersion portion 330 has a plate structure in which orifices are not formed. Preferably, though not required, the dispersion portion 330 has a disk structure.

The container 380 suppresses an abrupt change of a temperature of the inner chamber 310 by circulating a fluid to the inner chamber 310. The fluid circulated through the container 380 may be water or a GALDEN® solution or fluid. Preferably, though not required, in a temperature of 100° C. or less, water is used, and in a temperature of 100° C. or more, a GALDEN solution or fluid is used.

When the container 380 circulates the fluid to the inner chamber 310, a temperature of the inner chamber 310 is substantially constantly sustained and a temperature of the distribution plate 350 disposed within the inner chamber 310 is substantially constantly sustained. Accordingly, a property of a micro-crystalline silicon thin film layer formed in the substrate 370 is substantially uniformly sustained.

The heat exchanger 390 can exchange heat of the fluid circulated through the container 380. In order to perform an effective heat exchange, the heat exchanger 390 is preferably, though not required, disposed at the outside of the outer chamber 300.

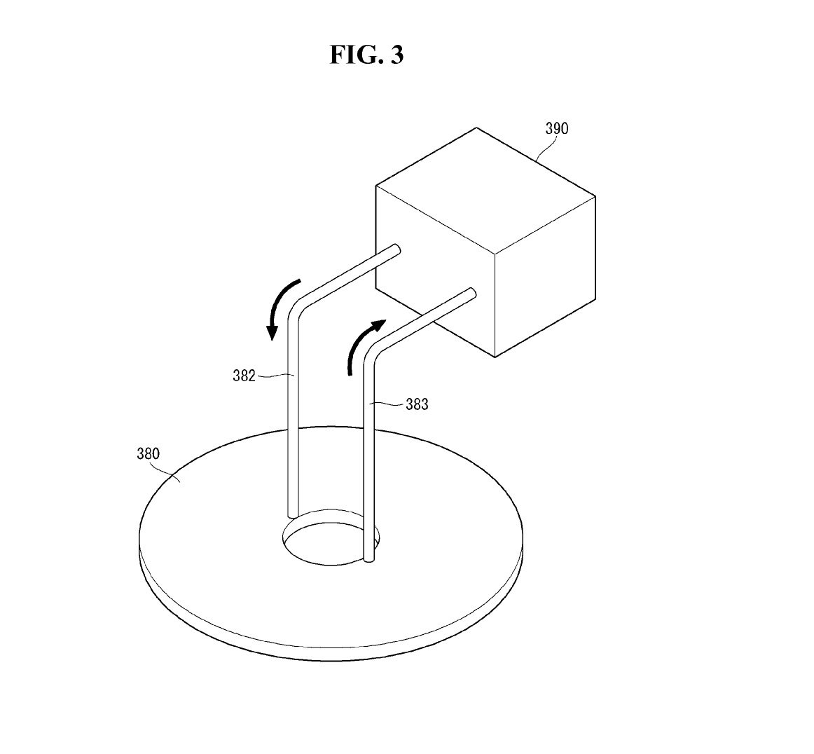

It is preferable that the container 380 has a hole (or a cavity) formed for storing a large amount of the fluid, as a case of FIG. 3.

The manufacturing apparatus according to an embodiment of the invention comprises a supply pipe 382 for supplying fluid from the heat exchanger 390 to the container 380 and a recovery pipe 383 for recovering fluid from the container 380 to the heat exchanger 390.

In order to constantly maintain a temperature of the distribution plate 350, the container 380 is formed parallel to the distribution plate 350. A cross-section of the container 380 has a shape of FIG. 2.

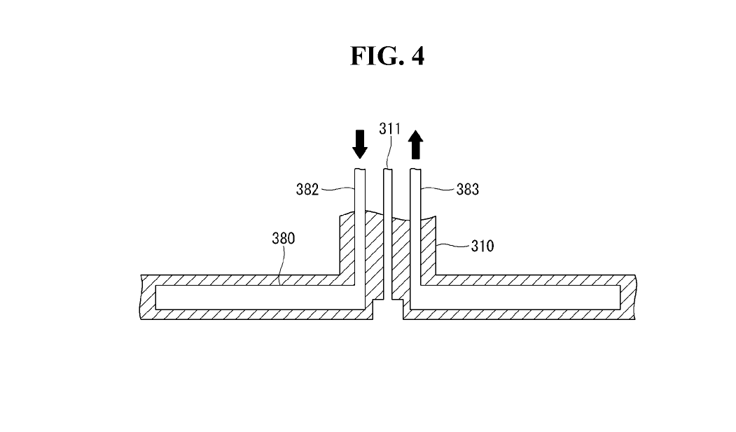

Further, the supply pipe 382 and the recovery pipe 383 may be disposed around the gas supply pipe 311 for supplying gas to the inner chamber 310, as in a case of FIG. 4.

In a structure of FIG. 4, before process gas is supplied into the inner chamber 310, a temperature of process gas is constantly maintained and thus a property of a silicon thin film layer can be more uniformly sustained.

When reaction gas is injected into the inner chamber 310 through the gas discharge port 320, the injected gas can be primarily dispersed by the dispersion portion 330 separated by a predetermined distance from the gas discharge port 320. Specifically, because the dispersion portion 330 has a plate form in which the orifice is not formed, the injected gas can be dispersed by flowing to a periphery of the dispersion portion 330.

Further, in order to improve gas dispersion efficiency by the dispersion portion 330, it is preferable, though not required, that an area of the dispersion portion 330 is larger than a sectional area of the gas discharge port 320.

As described above, a temperature of a process gas can be adjusted within a preset range using the heat exchanger 390 before dispersing the process gas injected into the inner chamber 310. That is, the temperature of the process gas can be set to a desired range before injecting the process gas into the inner chamber 310.

Thereafter, the gas dispersed by the dispersion portion 330 can be again secondarily dispersed by the distribution plate 350.

Specifically, the gas dispersed by the dispersion portion 330 and arrived in the distribution plate 350 can be more uniformly dispersed while passing through the orifices formed in the distribution plate 350.

The gas dispersed by the distribution plate 350 can be emitted to the substrate 370.

In this case, when radio frequency (RF) electric power or very high frequency (VHF) electric power is applied between the distribution plate 350, which is a negative electrode and the supporting member 360, which is a positive electrode, a plasma discharge occurs between the distribution plate 350 and the supporting member 360, and thus a thin film layer can be deposited on the substrate 370.

When such a method is used in a manufacturing process of a solar cell, a micro-crystalline silicon thin film layer may be deposited on the substrate 370.

In order to suppress an etching damage due to the plasma discharge, preferably, though not required, at least one of the distribution plate 350 and the dispersion portion 330 comprises an aluminum material (Al). More preferably, though not required, all of the distribution plate 350 and the dispersion portion 330 comprise an aluminum material (Al). Further, the distribution plate 350 can be formed integrally with the inner chamber 310. Further, the distribution plate 350 is made of the same material as that of the inner chamber 310.

Further, in order to more effectively deposit a micro-crystalline silicon thin film layer on the substrate 370 by plasma discharge generated between the distribution plate 350 and the supporting member 360, a gap between the substrate 370 and the distribution plate 350 should be fully small.

When a gap t1 between the substrate 370 and the distribution plate 350 is large, a deposition speed of the micro-crystalline silicon thin film layer becomes slow, and a sensitivity characteristic of the micro-crystalline silicon thin film layer may be worsened.

In order to fully reduce a gap t1 between the substrate 370 and the distribution plate 350, a gap between the distribution plate 350 and the supporting member 360 may be smaller than that between the distribution plate 350 and the dispersion portion 330. Accordingly, the gap between the substrate 370 and the distribution plate 350 is set to about 30 mm or less.

As described above, when gradually dispersing gas injected into the inner chamber 310 using the dispersion portion 330 and the distribution plate 350, the dispersed gas can be uniformly emitted to the substrate 370. Accordingly, a non-uniformity characteristic of a thickness of the micro-crystalline silicon thin film layer deposited in the substrate 370 can be improved. That is, a thickness of the micro-crystalline silicon thin film layer can be uniform.

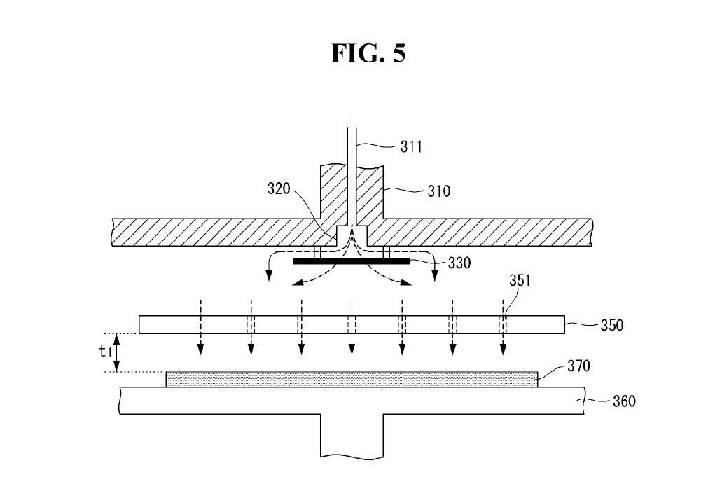

FIGS. 5 to 10 are views comparing a manufacturing apparatus according to an embodiment of the invention and a manufacturing apparatus according to a Comparative Example.

FIG. 5 illustrates an example of a manufacturing apparatus in which a container is not installed in the inner chamber 310.

In such a case, gas injected into the inner chamber 310 through the gas supply pipe 311 is dispersed by the distribution plate 350 and arrives at the substrate 370.

In this case, when electric power is applied between the distribution plate 350 and the supporting member 360, plasma discharge occurs between the distribution plate 350 and the supporting member 360. Accordingly, a micro-crystalline silicon thin film layer is formed on the surface of the substrate 370.

When the plasma discharge occurs between the distribution plate 350 and the supporting member 360, a temperature of the distribution plate 350 abruptly rises by the plasma discharge.

In this way, when a temperature of the distribution plate 350 abruptly rises by the plasma discharge within the inner chamber 310, a property of the micro-crystalline silicon thin film layer deposited in the substrate 370 may be affected.

In order to suppress the abrupt temperature rise by the plasma discharge having a harmful influence on a property of the micro-crystalline silicon thin film layer deposited in the substrate 370, a gap between the distribution plate 350 and the supporting member 360 can be fully widened.

However, when a gap between the distribution plate 350 and the supporting member 360 is excessively widened, a deposition speed of the silicon thin film layer may become excessively slow and a property of the silicon thin film layer may be worsened.

Therefore, it is difficult to excessively widen a gap between the distribution plate 350 and the supporting member 360.

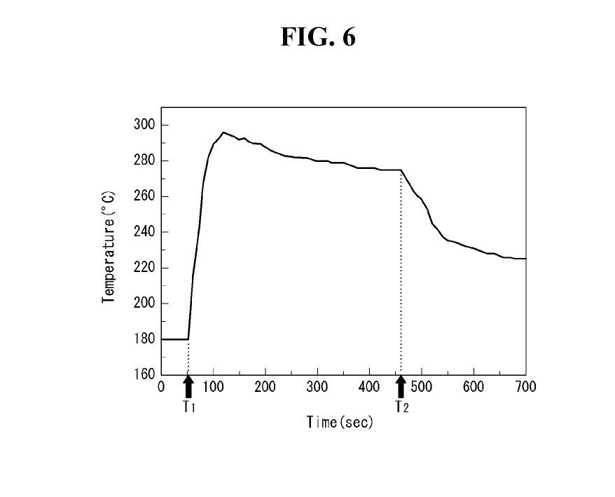

A measured temperature of a distribution plate when depositing a silicon thin film layer using the manufacturing apparatus having a configuration of FIG. 5 is shown in FIG. 6.

In an experiment condition when depositing a silicon thin film layer, power is about 0.7 W/cm², a process pressure is about 4 torr, a deposition temperature is about 180° C., and SiH₄ and H₂ are used as gas.

Further, a gap between the distribution plate 350 and the supporting member 360 is about 5 mm.

Referring to FIG. 6, at an initial time point T1 in which plasma discharge occurs between the distribution plate 350 and the supporting member 360, a temperature of the distribution plate 350 is about 180° C., and as plasma discharge is continued, a temperature of the distribution plate 350 rises to about 300° C. to a maximum, and then a temperature of the distribution plate 350 gradually decreases. Further, at a time point T2 in which plasma discharge is terminated, a temperature of the distribution plate 350 falls to about 250° C. or less.

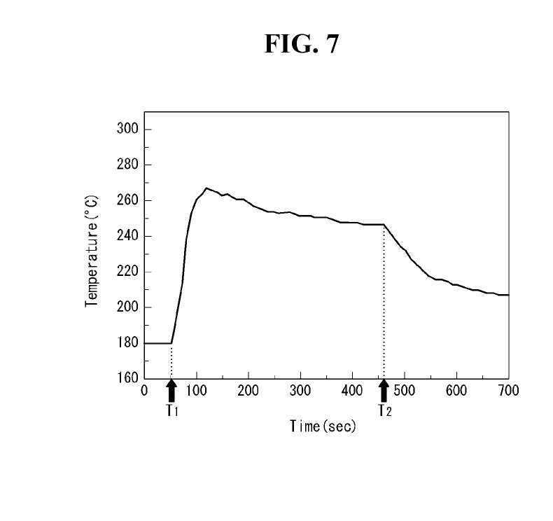

In FIG. 7, under the same experiment condition as that of FIG. 6, in a state where a gap between the distribution plate 350 and the supporting member 360 is widened to 10 mm, a temperature of the distribution plate 350 is measured.

Referring to FIG. 7, upon plasma discharge, a temperature of the distribution plate 350 rises to about 270° C. to a maximum and then gradually falls.

In cases of FIGS. 5 to 7, upon plasma discharge, a change width (or band) of a temperature of the distribution plate 350 is excessively large.

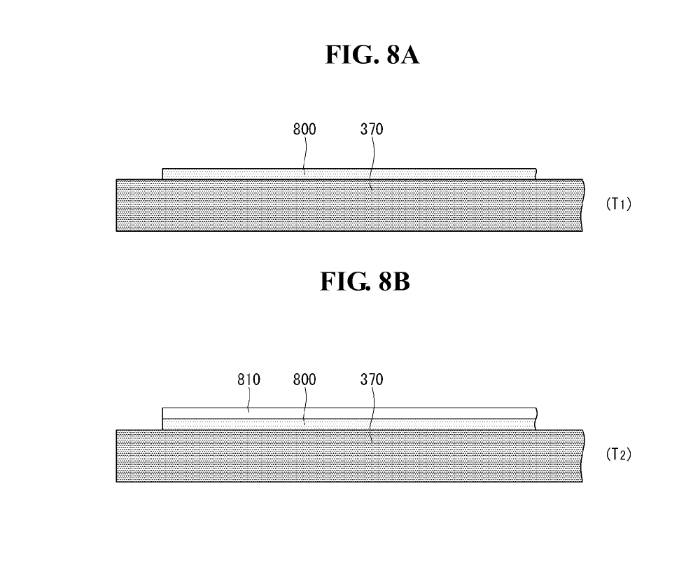

Therefore, as shown in FIG. 8A, at an initial time point T1 in which plasma discharge occurs, a difference between a crystallization degree of a micro-crystalline silicon thin film layer 800 formed in the substrate 370, and as shown in FIG. 8B, at a termination time point T2 in which plasma discharge occurs, a crystallization degree of a micro-crystalline silicon thin film layer 810 formed in the substrate 370 is very large.

Here, a crystallization degree represents a ratio of a silicon crystalline material comprised in the micro-crystalline silicon thin film layers 800 and 810.

In more detail, because a temperature of the distribution plate 350 at a time point T2 is relatively higher than that at a time point T1, the micro-crystalline silicon thin film layer 810 formed at the time point T2 has a property similar to an amorphous silicon material. That is, a crystallization degree of the micro-crystalline silicon thin film layer 810 formed at the time point T2 is relatively low as that of an amorphous silicon material.

Because a crystallization degree of the micro-crystalline silicon thin film layer 800 formed at a time point T1 is relatively high, crystallization degrees of the micro-crystalline silicon thin film layer 810 formed at the time point T2 and the micro-crystalline silicon thin film layer 800 formed at the time point T1 have a very larger difference.

In this way, when a difference of a crystallization degree increases in a thickness direction of the silicon thin film layer, a characteristic of the silicon thin film layer is worsened. For example, in a solar cell, photoelectric conversion efficiency may be excessively lowered.

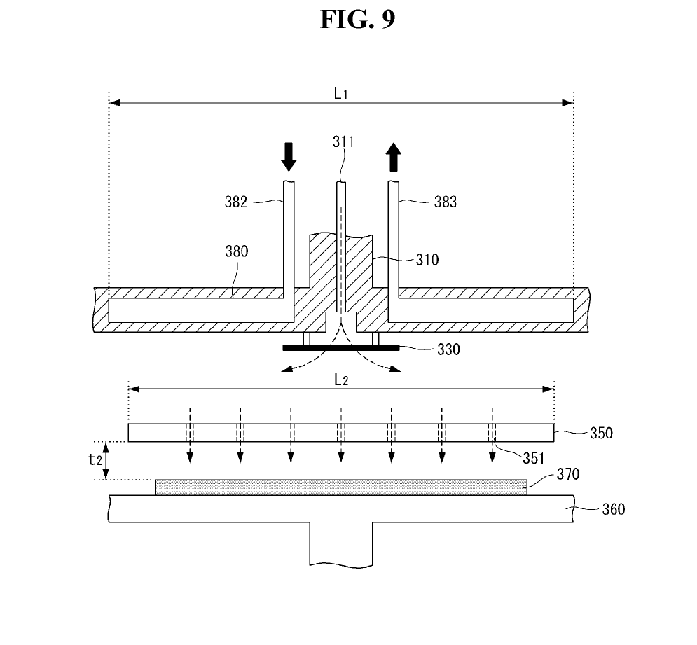

However, when a manufacturing apparatus having a configuration for circulating fluid is used in the inner chamber 310, as in a case of FIG. 9, a temperature of a process gas can be previously adjusted before injection of the process gas into the inner chamber 310. Accordingly, upon plasma discharge, a temperature of the distribution plate 350 can be substantially constantly sustained.

In such a configuration, in order to more effectively suppress a sudden change of a temperature of the distribution plate 350, it preferable, though not required, that a total length L1 of a horizontal direction of the container 380 is longer than or substantially equal to a total length L2 of a horizontal direction of the distribution plate 350.

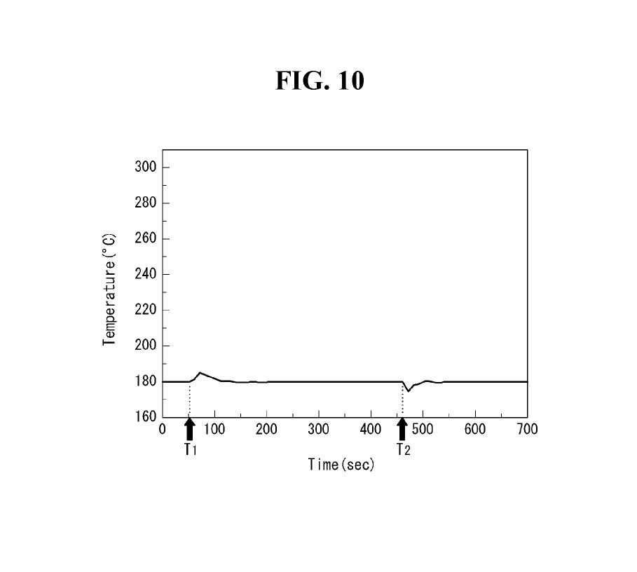

A measured temperature of a distribution plate when depositing a silicon thin film layer using a manufacturing apparatus having a configuration of FIG. 9 is shown in FIG. 10.

In an experiment condition when depositing a silicon thin film layer, power is about 0.7 W/cm², a process pressure is about 4 torr, a depositing temperature is about 180° C., and SiH₄ and H₂ are used as gas.

Further, a gap between the distribution plate 350 and the supporting member 360 is about 10 mm.

Referring to FIG. 10, at an initial time point T1 in which plasma discharge occurs between the distribution plate 350 and the supporting member 360, a temperature of the distribution plate 350 is about 180° C. and as plasma discharge is continued, a temperature of the distribution plate 350 rises to about 190° C. to a maximum, and then a temperature of the distribution plate 350 is substantially constantly sustained.

As can be seen through data of FIG. 10, when using the manufacturing apparatus according to an embodiment of the invention, even if plasma discharge occurs within the inner chamber, abrupt rise of a temperature of the distribution plate 350 can be suppressed. Substantially, even if the plasma discharge occurs, a temperature of the distribution plate 350 can be sustained within a range of about 170° C. to 190° C.

In this way, upon the plasma discharge, when a temperature of the distribution plate 350 is substantially constantly sustained, a crystallization degree of the micro-crystalline silicon thin film layer can be uniformly sustained in a thickness direction.

Further, a characteristic of a solar cell comprising the micro-crystalline silicon thin film layer manufactured by the above-described method is represented by Table 1.

TABLE 1

| | |
|---|---|
| Voc (V) | 1.385 |
| Jsc (mA/cm2) | 12.67 |
| F.F | 0.719 |
| Eff | 12.62 |

In Table 1, in the solar cell manufactured using the manufacturing apparatus according to an embodiment of the invention, Voc (V) is about 1.385V, Jsc (mA/cm²) is about 12.67 (mA/cm²), F.F is about 0.719, and efficiency thereof is about 12.62%.

As shown in Table 1, because efficiency of a solar cell manufactured using the manufacturing apparatus according to an embodiment of the invention is fully high, it can be seen that the solar cell is excellent.

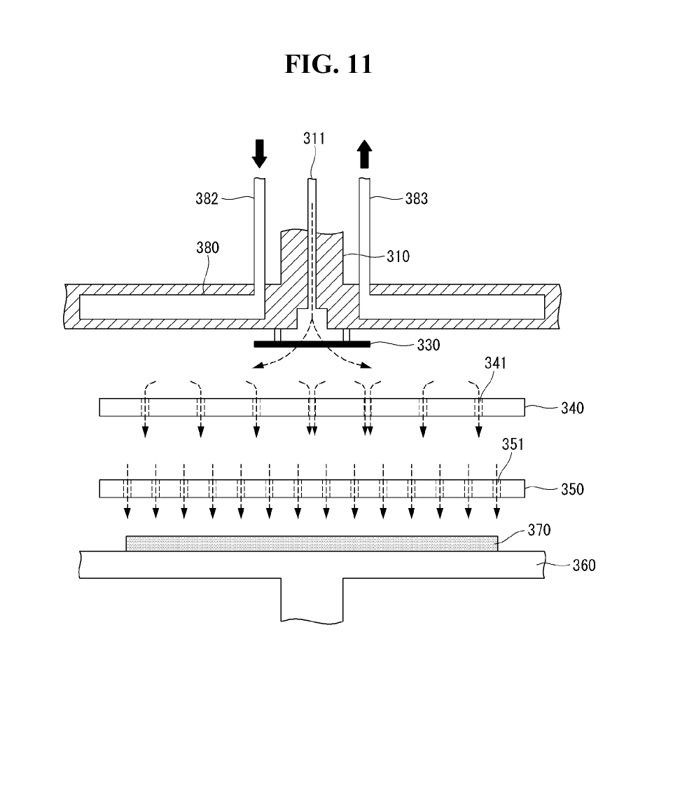

FIG. 11 is a view illustrating an example of another configuration of a silicon thin film layer manufacturing apparatus according to an embodiment of the invention. Hereinafter, a description of a portion described above in detail is omitted. For example, a description of an outer chamber and a heat exchanger is omitted hereinafter.

Referring to FIG. 11, a manufacturing apparatus of a silicon thin film layer according to an embodiment of the invention comprises an inner chamber 310, a dispersion portion 330 for dispersing gas supplied from a gas discharge port 320, a second distribution plate 340 for distributing gas supplied from the dispersion portion 330, and a first distribution plate 350 for redistributing gas passing through the second distribution plate 340.

The first distribution plate 350 is separated by a predetermined distance from a supporting member 360 and a substrate 370 within the inner chamber 310 and comprises a plurality of orifices.

Hereinafter, the orifices formed in the first distribution plate 350 are referred to as a first orifice. The first distribution plate 350 is used as a negative electrode.

The second distribution plate 340 comprises a plurality of orifices, as in the first distribution plate 350. Hereinafter, an orifice formed in the second distribution plate 340 is referred to as a second orifice.

The second distribution plate 340 is disposed between the first distribution plate 350 and the gas discharge port 320.

A second orifice 341 of the second distribution plate 340 is different from a first orifice 351 of the first distribution plate 350 in at least one of a gap, a width, and the number.

Specifically, the number of the second orifices 341 formed in the second distribution plate 340 may be smaller than that of the first orifices 351 formed in the first distribution plate 350. Preferably, though not required, in order to enhance gas dispersion efficiency of the first and second distribution plates 350 and 340, the number of the second orifices 341 formed in the second distribution plate 340 may be a half or less of the number of the first orifices 351 formed in the first distribution plate 350.

Alternatively, a gap between two adjacent second orifices 341 in the second distribution plate 340 may be larger than a gap between two adjacent first orifices 351 in the first distribution plate 350.

Alternatively, in order to enhance gas dispersion efficiency, a width, i.e., a diameter of the first orifice 351 having the relatively many number may be smaller than a diameter of the second orifice 341 having the relatively few number.

The dispersion portion 330 is disposed between the second distribution plate 340 and the gas discharge port 320.

When reaction gas is injected into the chamber 310 through the gas discharge port 320, the injected gas can be primarily dispersed by the dispersion portion 330 separated by a predetermined distance from the gas discharge port 320.

In this way, at a step of primarily dispersing gas using the dispersion portion 330, the injected gas can be dispersed into relatively wide space by flowing along the dispersion portion 330.

Thereafter, gas dispersed by the dispersion portion 330 can be again secondarily dispersed by the second distribution plate 340.

Specifically, gas dispersed by the dispersion portion 330 and arrived at the second distribution plate 340 can be more uniformly dispersed while passing through the second orifices 341 formed in the second distribution plate 340.

Thereafter, gas secondarily dispersed by the second distribution plate 340 can be thirdly dispersed by the first distribution plate 350.

Specifically, gas dispersed by the second distribution plate 340 and arrived at the first distribution plate 350 can be more uniformly dispersed while passing through the first orifice 351 formed in the first distribution plate 350.

The number of the first orifices 351 formed in the first distribution plate 350 is larger than that of the second orifices 341 formed in the second distribution plate 340, or a gap between the first orifices 351 is smaller than that between the second orifices 341 and thus gas can be more uniformly dispersed.

Gas dispersed by the first distribution plate 350 can be emitted to the substrate 370.

In this case, when plasma discharge occurs between the first distribution plate 350, which is a negative electrode and the supporting member 360, which is a positive electrode, a silicon thin film layer can be deposited on the substrate 370.

Preferably, though not required, at least one of the first distribution plate 350, the second distribution plate 340, and the dispersion portion 330 comprises an aluminum material (Al) in order to suppress etching damage due to the plasma discharge. More preferably, though not required, all of the first distribution plate 350, the second distribution plate 340, and the dispersion portion 330 comprise an aluminum material (Al). Further, at least one of the first distribution plate 350 and the second distribution plate 340 is formed integrally with the chamber 310. Further, at least one of the first distribution plate 350 and the second distribution plate 340 is made of the same material as that of the chamber 310.

In order to effectively deposit a thin film layer on the substrate 370, a gap between the supporting member 360 and the first distribution plate 350 is set to be smaller than that between the first distribution plate 350 and the dispersion portion 330. Preferably, though not required, the gap between the supporting member 360 and the first distribution plate 350 is smaller than at least one of a gap between the first distribution plate 350 and the second distribution plate 340 and a gap between the second distribution plate 340 and the dispersion portion 330.

As described above, when gradually dispersing gas injected into the chamber 310 using the dispersion portion 330, the second distribution plate 340, and the first distribution plate 350, the dispersed gas can be uniformly emitted to the substrate 370. Accordingly, a non-uniformity characteristic of a thickness of the micro-crystalline silicon thin film layer deposited in the substrate 370 can be improved. That is, a thickness of the micro-crystalline silicon thin film layer can be uniform.

Although embodiments have been described with reference to a number of illustrative embodiments thereof, it should be understood that numerous other modifications and embodiments may be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A silicon thin film layer manufacturing apparatus, comprising:
an outer chamber;
an inner chamber disposed within the outer chamber and having a supporting member on which a substrate is disposed;
a container disposed at the inner chamber, containing a fluid, and having a plate shape;
a heat exchanger disposed at the outside of the outer chamber and exchanging heat of the fluid;
at least one distribution plate disposed at the inner chamber and separated from the supporting member, the distribution plate having a plurality of orifices;
a gas discharge port supplying gas into the inner chamber; and
a dispersion portion disposed between the distribution plate and the gas discharge port, the dispersion portion having a plate structure lacking an orifice.

2. The silicon thin film layer manufacturing apparatus of claim 1, wherein the at least one distribution plate comprises a first distribution plate and a second distribution plate,
the second distribution plate is disposed between the discharge port and the supporting member, and
the first distribution plate is disposed between the second distribution plate and the supporting member.

3. The silicon thin film layer manufacturing apparatus of claim 2, wherein a number of plurality of orifices of the first distribution plate is larger than a number of plurality of orifices of the second distribution plate.

4. The silicon thin film layer manufacturing apparatus of claim 2, wherein a gap of plurality of orifices of the first distribution plate is smaller than a gap of plurality of orifices of the second distribution plate.

5. The silicon thin film layer manufacturing apparatus of claim 2, wherein a width of plurality of orifices of the first distribution plate is smaller than a width of plurality of orifices of the second distribution plate.

6. The silicon thin film layer manufacturing apparatus of claim 2, wherein at least one of the first distribution plate and the second distribution plate comprises an aluminum material (Al).

7. The silicon thin film layer manufacturing apparatus of claim 1, further comprising:
a supply pipe which supplies the fluid from the heat exchanger to the container; and
a recovery pipe which recovers the fluid from the container to the heat exchanger.

8. The silicon thin film layer manufacturing apparatus of claim 7, further comprising a gas supply pipe which supplies gas into the gas discharge port, wherein the supply pipe and the recovery pipe are disposed around the gas supply pipe.
